(19) United States
(12) Patent Application Publication
(10) Pub. No.: US 2011/0134618 A1
(43) Pub. Date: Jun. 9, 2011

(54) CONNECTION STRUCTURE FOR CHIP-ON-GLASS DRIVER IC AND CONNECTION METHOD THEREFOR

(75) Inventors: Wei-hao Sun, Wugu (TW); Pao-yun Tang, Wugu (TW)

(73) Assignee: HANNSTAR DISPLAY CORPORATION, Wugu (TW)

(21) Appl. No.: 12/762,328

(22) Filed: Apr. 17, 2010

(30) Foreign Application Priority Data
Dec. 3, 2009 (TW) 098141403

(51) Int. Cl. H05K 7/12

(52) U.S. Cl. 361/768

(57) ABSTRACT

A connection structure for a chip-on-glass (COG) driver IC and a connection method therefor are provided. The connection structure includes a driver IC having a surface provided with a plurality of polymeric bumps and a plurality of conductive bumps, and the height of the polymeric bumps in relation to the surface is smaller than that of the conductive bumps. When the driver IC is bonded to a glass substrate via an adhesive film by thermal compression bonding, the polymeric bumps are embedded into the adhesive film, and a gap is defined between the polymeric bumps and the glass substrate. Thus, the polymeric bumps can increase the contact area between the driver IC and the adhesive film, and enhance the connection reliability between the conductive bumps and pads of the glass substrate.

### FIELD OF THE INVENTION

The present invention relates to a connection structure for a chip-on-glass (COG) driver IC and a connection method therefor, and more particularly to a connection structure for a COG driver IC having polymeric bumps to increase the connection reliability thereof when connecting to a glass substrate via an adhesive film and a connection method for the COG driver IC.

### BACKGROUND OF THE INVENTION

Presently, various audio video electronic products are now in widespread use, so as to further promote the rapid development of various image display technologies, wherein common image display technologies includes liquid crystal display (LCD), plasma display panel (PDP), digital light processing (DLP) and etc. The foregoing image display technologies are generally applied to various electronic products, such as computer monitors, televisions, mobile phones, digital cameras, digital video cameras, MP3 players, game consoles, other 3C products and etc. The development trend of the foregoing applications of the electronic products is miniaturization and compactness, so that it is necessary to develop packaging technologies for driver ICs to provide higher density, smaller volume, and more convenient installation. To satisfy these needs, chip on film (COF) packaging technologies and chip on glass (COG) packaging technologies are thus rapidly developed and applied, so as to become the main packaging technologies for driver ICs of flat panel displays (FPD).

Referring now to FIG. 1, a traditional chip-on-glass (COG) package structure of liquid crystal display (LCD) is illustrated, wherein a glass substrate 10 is provided with a liquid crystal device 11 and a plurality of anisotropic conductive film (ACF) 12, 12′. The ACF 12 is used to connect to a driver IC (integrated circuit) 13, while the ACF 12′ is used to connect to a flexible printed circuit (FPC) board 14 which is further connected to other control circuits. Thus, the driver IC 13 can be used to drive the liquid crystal device 11 to generate colors and variations thereof for forming and displaying images.

Referring now to FIGS. 2A and 2B, a traditional connection structure for driver IC is illustrated, wherein an active surface of the driver IC 13 has a plurality of gold bumps 131, the ACF 12 comprises a plurality of conductive particles 121 therein, and an upper surface of the glass substrate 10 has a plurality of pads 101. The gold bumps 131 of the driver IC 13 can press downward and contact the conductive particles 121 of the ACF 12 by thermal compression bonding, so that the gold bumps 131 can be connected to the pads 101 of the glass substrate 10 via the conductive particles 121. The driver IC 13 having the connection structure of the ACF 12 is one of currently main packaging technologies of driver ICs. However, the disadvantages of the driver IC 13 are described, as follows: when the pitch of the gold bumps 131 is reduced and the distribution density thereof is increased, a short-circuit problem may be easily generated due to the conductive particles 121 disposed between each two of the adjacent gold bumps 131 which may unexpectedly connect the adjacent gold bumps 131 with each other.

To solve the foregoing problems, referring now to FIGS. 3A and 3B, another traditional connection structure for driver IC is illustrated, wherein the driver IC 13 is attached to the glass substrate 10 via a non-conductive adhesive film (NCF) 15 by thermal compression bonding, wherein the gold bumps 131 are directly electrically contact the pads 101 for the purpose of electrical connection. The driver IC 13 having the connection structure of the NCF 15 is advantageous to shorten the pitch of the gold bumps and increase the distribution density thereof, so that this type of the driver IC 13 can be used to carry out the miniaturization and compactness of electronic products or the enhancement of image quality. However, disadvantages of the connection structure of the NCF 15 are described, as follows: because the NCF 15 has no conductive particles therein, it must ensure that the gold bumps 131 can surely and stably contact the pads 101, i.e. the allowable warpage of the driver IC 13 must be controlled to a lower extent and the holding force of the NCF 15 for holding the driver IC 13 must be sufficient. However, as shown in FIG. 3C, after the process of thermal compression bonding, because the direction of thermal stress generated due to the difference of coefficient of thermal expansion (CTE) between the driver IC 13, the NCF 15 and the glass substrate 10 is opposite to that of the holding force of the NCF 15 for holding the driver IC 13, it may easily generate vacuum holes 151 due to the stress tension. As a result, some of the vacuum holes 151 may narrow the contact area between the gold bumps 131 and the pads 101, and affect the connection quality and production yield of the driver IC 13. Meanwhile, the foregoing technical problems will limit the technological development trend for using the NCF 15 to shorten the pitch of the gold bumps 131 and increase the distribution density thereof.

As a result, it is necessary to provide a connection structure for a chip-on-glass (COG) driver integrated circuit (IC) and a connection method therefor to solve the problems existing in the traditional connection structures for driver IC, as described above.

### SUMMARY OF THE INVENTION

A primary object of the present invention is to provide a connection structure for a chip-on-glass (COG) driver IC, wherein a surface of a driver IC is provided with polymeric bumps to increase the contact area between the driver IC and an adhesive film and to enhance the connection strength of the adhesive film for holding the driver IC, so as to overcome the thermal stress generated during the process of thermal compression bonding and to reduce the risk of forming vacuum holes generated between conductive bumps and pads. As a result, the connection reliability between the conductive bumps and the pads can be enhanced, and the packaging yield of the driver IC can be improved.

A secondary object of the present invention is to provide a connection structure for a COG driver IC and a connection method therefor, wherein photosensitive polymer is used to form a polymer layer which is processed by processes of exposure and development to form a plurality of polymeric bumps, so as to simplify the process of the polymeric bumps and increase the height uniformity of the polymeric bumps.

To achieve the above object, a driver IC structure of one embodiment of the present invention is provided and comprises a surface, a plurality of polymeric bumps and a plurality of conductive bumps, wherein the polymeric bumps and the conductive bumps are arranged on the surface and the height of the polymeric bumps relative to the surface is smaller than that of the conductive bumps relative to the surface.

In one aspect of the present invention, the polymeric bumps are made of photosensitive polymer.

In one aspect of the present invention, the photosensitive polymer is polyimide (PI).

In one aspect of the present invention, the conductive bumps are gold bumps.

In one aspect of the present invention, each of the conductive bumps is formed on a pad on the surface of the driver IC and at least one of the polymeric bumps surrounding the pad thereon.

In one aspect of the present invention, each of the conductive bumps is directly formed on a pad on the surface of the driver IC.

In one aspect of the present invention, the coefficient of thermal expansion (CTE) of the polymeric bumps is greater than that of a substrate of the driver IC.

In one aspect of the present invention, the CTE difference between the polymeric bumps and an adhesive film is smaller than that between the substrate of the driver IC and the adhesive film.

In one aspect of the present invention, the conductive bumps are arranged on a peripheral region of the surface of the driver IC, and most of the polymeric bumps are substantially arranged on a central region of the surface of the driver IC surrounded by the conductive bumps.

Furthermore, another embodiment of the present invention is to provide a connection structure for a chip-on-glass driver IC, wherein the connection structure comprises a glass substrate, a driver IC and an adhesive film, wherein the glass substrate has a surface formed with a plurality of pads; the driver IC has a surface, a plurality of polymeric bumps and a plurality of conductive bumps which are arranged on the surface of the driver IC and electrically connected to the pads, wherein the polymeric bumps are arranged on the surface of the driver IC and the height of the polymeric bumps relative to the surface of the driver IC is smaller than that of the conductive bumps relative to the surface of the driver IC; and the adhesive film is used to attach the driver IC to the glass substrate, and to encapsulate the polymeric bumps, the conductive bumps and the pads, wherein the polymeric bumps are embedded in the adhesive film and a gap is defined between the polymeric bumps and the surface of the glass substrate.

In one aspect of the present invention, the coefficient of thermal expansion (CTE) of the polymeric bumps is greater than that of the glass substrate.

In one aspect of the present invention, the CTE difference between the polymeric bumps and the adhesive film is smaller than that between the glass substrate and the adhesive film.

In one aspect of the present invention, the adhesive film is a non-conductive adhesive film (NCF).

In one aspect of the present invention, the adhesive film is an anisotropic conductive film (ACF) having a plurality of conductive particles therein.

In one aspect of the present invention, the height difference between the polymeric bumps and the conductive bumps is greater than the particle diameter of the conductive particles.

Moreover, further another embodiment of the present invention is to provide a manufacturing method for a driver IC, wherein the manufacturing method comprising steps of: providing a wafer having a surface formed with a plurality of pads; forming a polymer layer on the surface of the wafer; processing the polymer layer by processes of exposure and development to form a plurality of polymeric bumps; forming a plurality of conductive bumps on the pads, wherein the height of the conductive bumps relative to the surface is greater than that of the polymeric bumps relative to the surface; and cutting the wafer into a plurality of driver ICs.

In one aspect of the present invention, the polymer layer is made of photosensitive polymer.

In one aspect of the present invention, the photosensitive polymer is polyimide (PI).

In addition, still further another embodiment of the present invention is to provide a connection method for a chip-on-glass driver IC, wherein the connection method comprising steps of: providing a driver IC having a surface, a plurality of polymeric bumps and a plurality of conductive bumps, wherein the polymeric bumps and the conductive bumps are arranged on the surface and the height of the polymeric bumps relative to the surface is smaller than that of the conductive bumps relative to the surface; and attaching the driver IC to a glass substrate via an adhesive film by thermal compression bonding, wherein the conductive bumps are electrically connected to a plurality of pads on the glass substrate, the polymeric bumps are embedded in the adhesive film, and a gap is defined between the polymeric bumps and a surface of the glass substrate.

### DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an assembled perspective view of a traditional chip-on-glass (COG) package structure of liquid crystal display (LCD);

FIGS. 2A and 2B are cross-sectional views of a traditional connection structure for driver IC before or after installation;

FIGS. 3A and 3B are cross-sectional views of another traditional connection structure for driver IC before or after installation;

FIG. 3C is a partially enlarged view of FIG. 3B;

FIGS. 4A and 4B are cross-sectional views of a connection structure for a chip-on-glass driver IC and a connection method therefor according to a first embodiment of the present invention;

FIGS. 5A, 5B, 5C and 5D are schematic views of the manufacturing method for a driver IC structure according to the first embodiment of the present invention; and

FIGS. 6A and 6B are cross-sectional views of a connection structure for a chip-on-glass driver IC and a connection method therefor according to a second embodiment of the present invention.

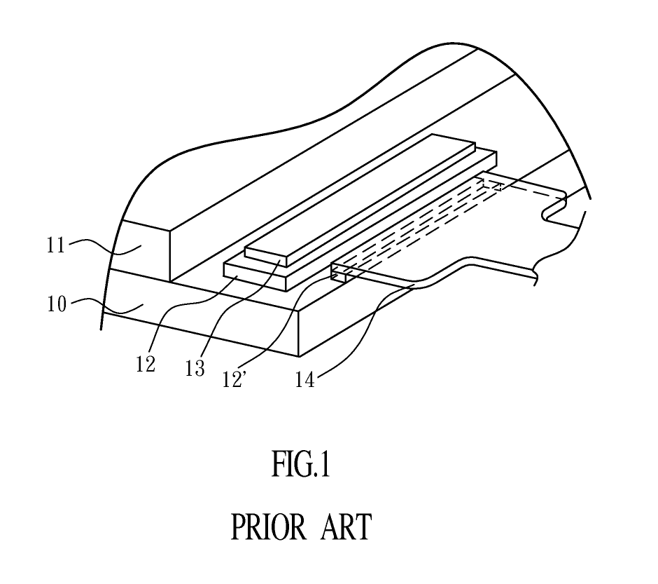

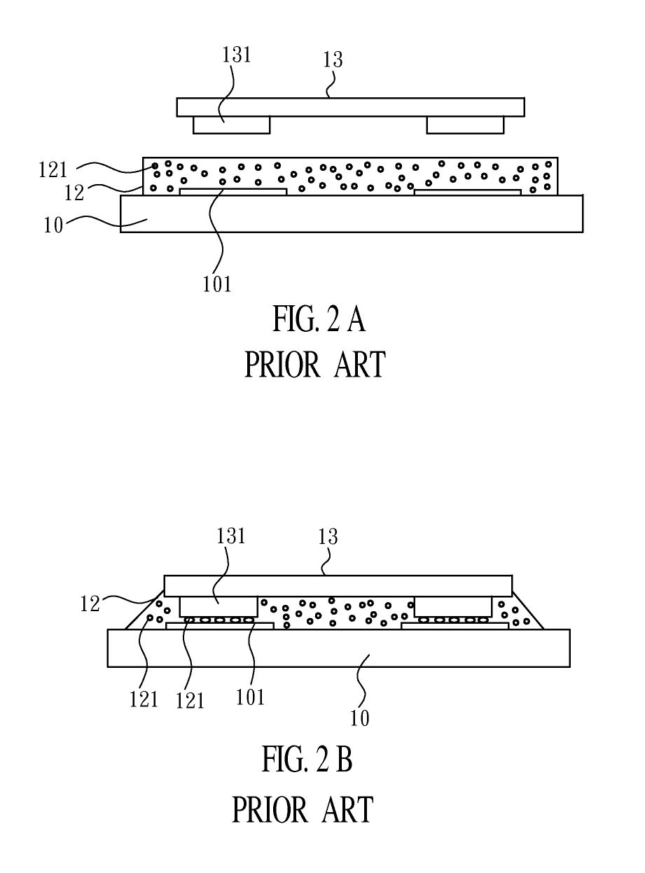

### DETAILED DESCRIPTION OF THE PREFERRED EMBODIMENTS

The present invention discloses a connection structure for a chip-on-glass (COG) driver IC and a connection method therefor, both of which can be applied to technologies fields of various image display devices or image capturing devices, wherein the image display devices can be selected from liquid crystal display (LCD), plasma display panel (PDP), digital light processing (DLP), electro-phoretic display (EPD, i.e. electronic paper display) or other display devices, while the image capturing devices can be selected from camera lens module, video camera lens module or other image sensors, but not limited thereto.

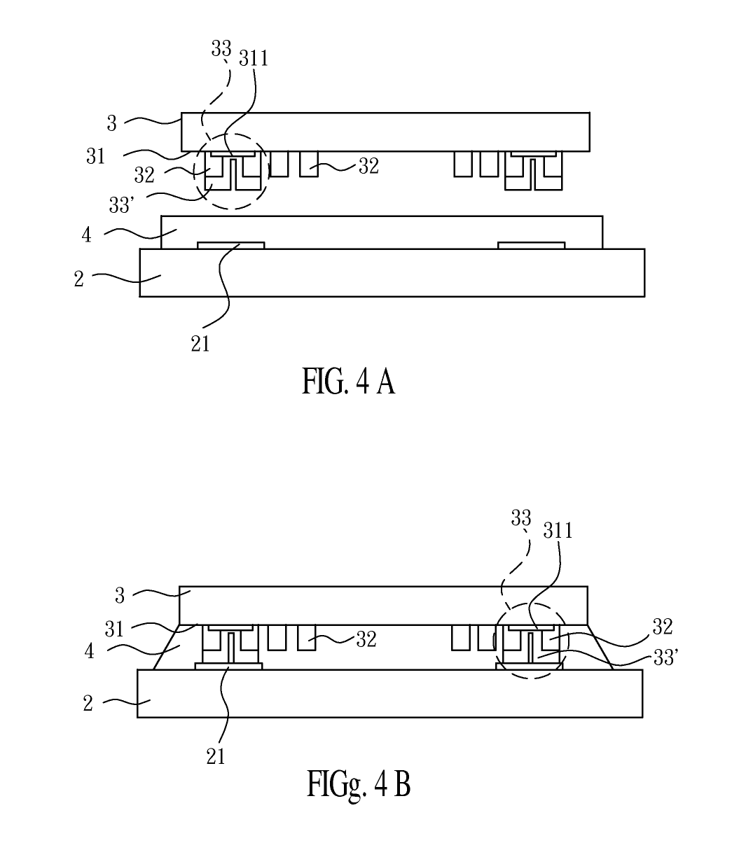

Referring now to FIGS. 4A and 4B, a connection structure for a chip-on-glass (COG) driver IC according to a first embodiment of the present invention is illustrated. As shown, the connection structure comprises a glass substrate 2, a driver IC 3 and an adhesive film 4, wherein the glass substrate 2 is preferably selected from a glass plate having a transparent conductive layer which is preferably indium-tin oxide (ITO) and can be used to form a plurality of pads 21. The driver IC 3 is preferably a rectangular silicon chip cut from a silicon wafer, and has a surface 31, a plurality of polymeric bumps 32 and a plurality of conductive bumps 33, wherein the surface 31 has an insulation protection layer (not shown) and a plurality of pads 311 which are exposed by the insulation protection layer to electrically connect to the conductive bumps 33. The polymeric bumps 32 and the conductive bumps 33 are arranged on the surface 31. In the embodiment, the polymeric bumps 32 are made of photosensitive polymer, such as polyimide (PI) or equivalent. Furthermore, the conductive bumps 33 include a metal layer, such as gold (Au), and each of the conductive bumps 33 is electrically connected to the pads 311 of the surface 31. Each of the conductive bumps 33 covers at least one of the polymeric bumps 32. For example, as shown in FIG. 4A, two or more of the polymeric bumps 32 surround the same pad 311 and cover a portion of the pad 311, while the polymeric bumps 32 expose the other portion of the pad 311, wherein each of the conductive bumps 33 essentially includes the polymeric bumps 32 surrounding the conductive bump 33. According to the foregoing structure, the maximum height of the conductive bumps 33 relative to the surface 31 is preferably controlled to be ranged from 10 um to 15 um, while the maximum height of the polymeric bumps 32 relative to the surface 31 is preferably controlled to be ranged from 5 um to 10 um. Especially, the height of the polymeric bumps 32 is controlled to be smaller than that of the conductive bump 33. In addition, in the present invention, the conductive bumps 33 are preferably arranged on a peripheral region of the surface 31, and most of the polymeric bumps 32 are substantially arranged on a central region of the surface 31 surrounded by the conductive bumps 33.

Referring still to FIGS. 4A and 4B, in the first embodiment of the present invention, the adhesive film 4 is selected from a non-conductive adhesive film (NCF) which is made of adhesive resin material without conductivity. The adhesive film 4 has no any conductive particles therein, and is used to attach the driver IC 3 to the glass substrate 2. After installation, the adhesive film 4 encapsulates (i.e. covers) the polymeric bumps 32, the conductive bumps 33 and the pads 21, wherein the polymeric bumps 32 are embedded into the adhesive film 4, and a predetermined gap is defined between the polymeric bumps 32 and a surface of the glass substrate 2 due to the difference between the height of the polymeric bumps 32 and the height of the conductive bumps 33. As a result, a lower surface and four side surfaces of each of the polymeric bumps 32 can be directly in contact with the adhesive film 4, so that the total contact area between the surface 31 of the driver IC 3 and the adhesive film 4 can be increased. In the present invention, the coefficient of thermal expansion (CTE) of the glass substrate 2, the driver IC 3, and the adhesive film 4 must be suitably controlled, wherein the material of the polymeric bumps 32 is selected, so that the CTE of the polymeric bumps 32 can be greater than that of the substrate of the driver IC 3 and/or that of the glass substrate 2. Meanwhile, the CTE difference between the polymeric bumps 32 and the adhesive film 4 is smaller than that between the substrate of the driver IC 3 and the adhesive film 4 and/or that between the substrate of the glass substrate 2 and the adhesive film 4. In other words, in comparison with the driver IC 3 or the glass substrate 2, the CTE of the polymeric bumps 32 is closer to that of the adhesive film 4. For example, if the material of the polymeric bumps 32 is polyimide (Pl), the CTE of the polymeric bumps 32 is about 47-55 ppm/° C.; if the substrate of the driver IC 3 is silicon, the CTE of the driver IC 3 is about 2.5 ppm/° C.; the CTE of the glass of the glass substrate 2 is about 4.0 ppm/° C.; and the material of the adhesive film 4 is selected from various adhesive polymeric resins, wherein the CTE thereof is about 50-70 ppm/° C., but not limited thereto.

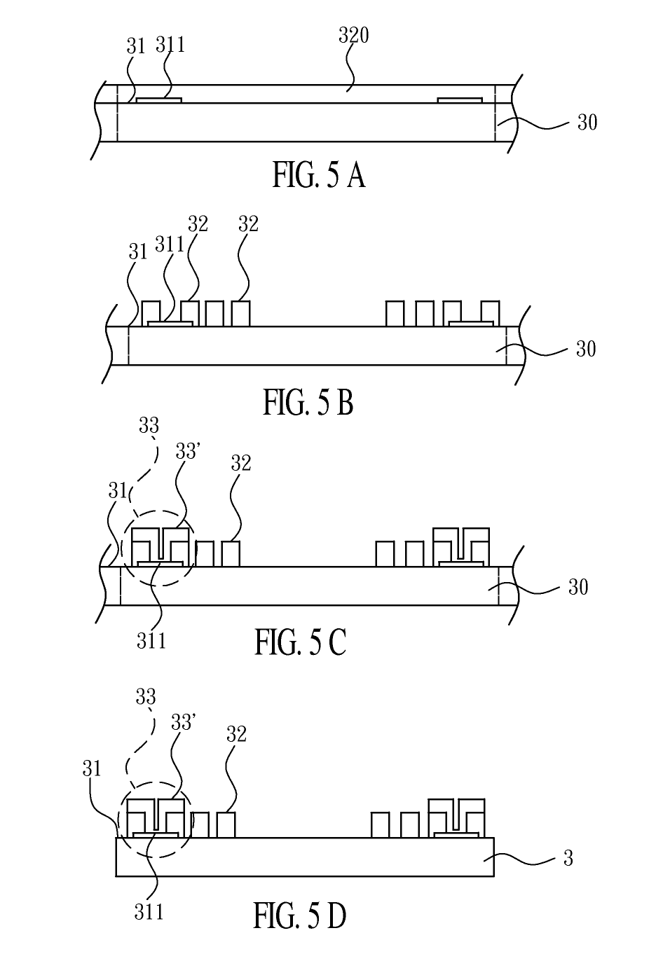

Referring now to FIGS. 5A, 5B, 5C and 5D, a manufacturing method for a driver IC according to the first embodiment of the present invention is illustrated, wherein the manufacturing method comprises the following steps of: providing a wafer 30 having a surface 31 formed with a plurality of pads 311; forming a polymer layer 320 on the surface 31 of the wafer 30; processing the polymer layer 320 by processes of exposure and development to form a plurality of polymeric bumps 32; forming a plurality of conductive bumps 33 on the pads 311, wherein the height of the conductive bumps 33 relative to the surface 31 is greater than that of the polymeric bumps 32 relative to the surface 31; and cutting the wafer 30 into a plurality of driver ICs 3.

In detail, as shown in FIG. 5A, according to the manufacturing method, the wafer 30 is preferably selected from a silicon wafer, but not limited thereto. The surface 31 has a plurality of pads 311 thereon. The present invention can form the polymeric layer 320 by spin coating, printing or attaching, wherein the polymer layer 320 is made of photosensitive polymer, such as polyimide (Pl), which can provide similar property of positive or negative photoresist. Furthermore, as shown in FIG. 5B, according to the manufacturing method, the present invention can firstly process the polymeric layer 320 by traditional process of photomask exposure, and then process the polymeric layer 320 by suitable development solution, so that the polymeric layer 320 can be patterned to form the plurality of polymeric bumps 32. The foregoing step is advantageous to simplify the process of the polymeric bumps 32.

Then, as shown in FIG. 5C, according to the manufacturing method, the present invention can firstly form a photoresist layer (not-shown) by coating or attaching, and then pattern the photoresist layer by processes of exposure and development, so as to expose at least one portion of each of the pads 311 and the polymeric bumps 32 surrounding the pad 311. After this, a process of a first metal layer is executed to form the first metal layer on the surface of the pad 311 and the polymeric bumps 32 surrounding the pad 311 (not-shown). Then, a bumping process of the conductive bumps 33 is executed by plating or printing, so as to further form a conductive layer 33′ on the first metal layer, wherein the conductive layer 33′ is made of gold, but also can be made of other metals, such as gold alloy, tin, tin alloy and etc. Each of the conductive bumps 33 includes the conductive layer 33′, the first metal layer and the polymeric bumps 32 surrounding the pad 311, wherein the conductive bump 33 is electrically connected to the pad 311, the maximum height of the conductive bump 33 relative to the surface 31 is preferably controlled to be ranged from 10 um to 15 um, while the maximum height of the polymeric bumps 32 relative to the surface 31 is preferably controlled to be ranged from 5 um to 10 um. The height of the conductive bump 33 is controlled to be greater than that of the polymeric bumps 32. Finally, as shown in FIG. 5D, according to the manufacturing method, the present invention can cut the wafer 30 into a plurality of driver ICs 3 by sawing wheel, waterjet, laser or the combination thereof.

Referring back to FIGS. 4A and 4B, in the first embodiment of the present invention, after the manufacturing method of the driver IC is finished, the connection method for a chip-on-glass (COG) driver IC is carried out, wherein the connection method comprises the following steps of: providing a driver IC 3 having a surface 31, a plurality of polymeric bumps 32 and a plurality of conductive bumps 33, wherein the polymeric bumps 32 and the conductive bumps 33 are arranged on the surface 31 and the height of the polymeric bumps 32 relative to the surface 31 is smaller than that of the conductive bumps 33 relative to the surface 31; and attaching the driver IC 3 to a glass substrate 2 via an adhesive film 4 by thermal compression bonding, wherein the conductive bumps 33 are electrically connected to a plurality of pads 21 on the glass substrate 2, the polymeric bumps 32 are embedded in the adhesive film 4, and a gap is defined between the polymeric bumps 32 and a surface of the glass substrate 2.

According to the foregoing connection method, the adhesive film 4 is selected from a non-conductive adhesive film (NCF). During the process of thermal compression bonding, the adhesive film 4 encapsulates (i.e. covers) the polymeric bumps 32, the conductive bumps 33 and the pads 21, wherein a predetermined gap is defined between the polymeric bumps 32 and a surface of the glass substrate 2 due to the difference between the height of the polymeric bumps 32 and the height of the conductive bumps 33. As a result, the polymeric bumps 32 can increase the contact area between the driver IC 3 and the adhesive film 4 without affecting the stable connection of the conductive bumps 33 and the pads 21. Furthermore, because each of the conductive bumps 33 is formed on one of the pads 311 of the surface 31 and at least one of the polymeric bumps 32 surrounding the pad 311, the polymeric bumps 32 below the conductive bumps 33 can further provide suitable buffering elasticity to ensure the contact between the conductive bumps 33 and the pads 21. Especially, a lower surface and four side surfaces of each of the polymeric bumps 32 can be directly in contact with the adhesive film 4, so that the total contact area between the surface 31 of the driver IC 3 and the adhesive film 4 can be increased, while the connection strength of the adhesive film 4 for holding the driver IC 3 can be enhanced. In addition, the CTE of the polymeric bumps 32 is relatively closer to that of the adhesive film 4. During the thermal expansion or contraction of the adhesive film 4, the polymeric bumps 32 will thermally expanded or contracted corresponding to the adhesive film 4 at the same time. Thus, the present invention can maintain the tight contact between each surface of the polymeric bumps 32 and the adhesive film 4. As a result, the present invention can overcome the thermal stress generated during the process of thermal compression bonding, so as to reduce the risk of forming vacuum holes generated between the conductive bumps 33 and the pads 21. Therefore, the connection reliability between the conductive bumps 33 and the pads 21 can be enhanced, and the packaging yield of the driver IC 3 can be improved.

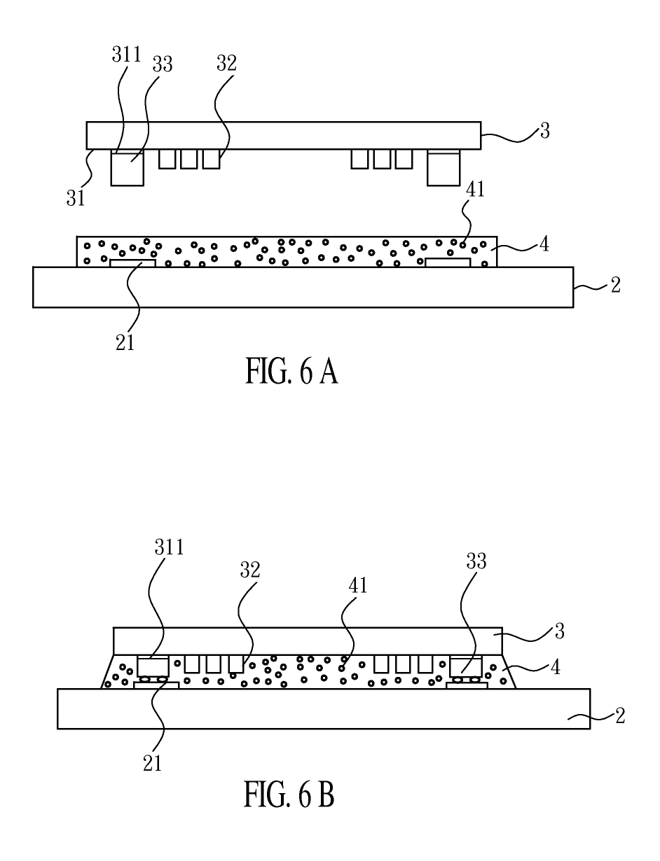

Referring now to FIGS. 6A and 6B, a connection structure for a chip-on-glass driver IC and a connection method therefor according to a second embodiment of the present invention is illustrated and similar to the first embodiment, so that the second embodiment uses similar numerals of the first embodiment. As shown, the connection structure for the COG driver IC and the connection method therefor of the second embodiment are characterized in that the present invention directly forms each of the conductive bumps 33 on each of corresponding pads 311 on the surface 31 of the driver IC 3 by traditional processes of patterned photoresist and plating (or printing), wherein the conductive bumps 33 are preferably selected from gold bumps, but also can be selected from other metals, such as gold alloy, tin, tin alloy and etc. Furthermore, the adhesive film 4 is selected from an anisotropic conductive film (ACF) which has a plurality of conductive particles 41 therein. The conductive particles 41 can electrically connect the conductive bumps 33 to the pads 21. In addition, a suitable difference between the height of the polymeric bumps 32 and that of the conductive bumps 33 is also kept, so that a corresponding gap can be defined between the polymeric bumps 32 and the surface of the glass substrate 2. Meanwhile, the difference between the height of the polymeric bumps 32 and the height of the conductive bumps 33 is greater than the particle diameter of the conductive particles 41, in order to prevent the conductive particles 41 from contacting with surface circuits (not-shown) of the glass substrate 2 due to the unexpected push of the polymeric bumps 32. In a case that the adhesive film 4 is selected from ACF, a lower surface and four side surfaces of each of the polymeric bumps 32 according to the second embodiment of the present invention also can be directly in contact with the adhesive film 4, so that the total contact area between the surface 31 of the driver IC 3 and the adhesive film 4 can be increased, while the connection strength of the adhesive film 4 for holding the driver IC 3 can be enhanced. As a result, the risk of forming vacuum holes generated between the conductive bumps 33 and the pads 21 also can be reduced. Therefore, the connection reliability between the conductive bumps 33 and the pads 21 also can be enhanced, and the packaging yield of the driver IC 3 also can be improved.

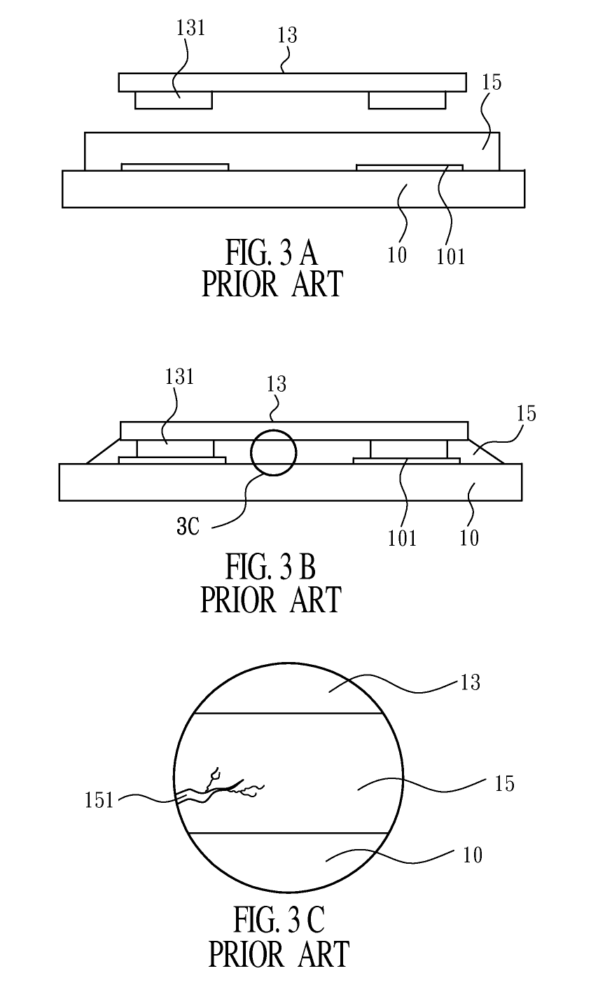

As described above, as shown in FIGS. 3A and 3B, the traditional driver IC 13 may easily generate vacuum holes 151 between the gold bumps 131 and the pads 101 due to the stress tension after the process of thermal compression bonding, and thus the connection quality and production yield of the driver IC 13 are reduced. In comparison with the traditional driver IC 13, as shown in FIGS. 4A to 6B, the connection structure for the chip-on-glass driver IC and the connection method therefor according to the present invention are provided, wherein the surface 31 of the driver IC 3 is provided with the polymeric bumps 32 to increase the contact area between the driver IC 3 and the adhesive film 4 and to enhance the connection strength of the adhesive film 4 for holding the driver IC 3, so as to overcome the thermal stress generated during the process of thermal compression bonding and to reduce the risk of forming vacuum holes generated between the conductive bumps 33 and the pads 21. As a result, the connection reliability between the conductive bumps 33 and the pads 21 can be enhanced, and the packaging yield of the driver IC 3 can be improved. Furthermore, it meets the trend of using NCF as the adhesive film 4 to efficiently shorten the pitch of the conductive bumps 33 and increase the distribution density thereof. In addition, the connection method of the present invention uses photosensitive polymer to form the polymer layer 320 which is processed by processes of exposure and development to form the plurality of polymeric bumps 32, so as to simplify the process of the polymeric bumps 32 and increase the height uniformity of the polymeric bumps 32, and to increase the contact area between the driver IC 3 and the adhesive film 4 without affecting the stable connection of the conductive bumps 33 and the pads 21.

The present invention has been described with a preferred embodiment thereof and it is understood that many changes and modifications to the described embodiment can be carried out without departing from the scope and the spirit of the invention that is intended to be limited only by the appended claims.

What is claimed is:

1. A connection structure for a chip-on-glass driver IC, comprising:
a glass substrate having a surface formed with a plurality of pads;
a driver IC having a surface, a plurality of polymeric bumps and a plurality of conductive bumps which are electrically connected to the pads, wherein the height of the polymeric bumps relative to the surface of the driver IC is smaller than that of the conductive bumps relative to the surface of the driver IC; and
an adhesive film for attaching the driver IC to the glass substrate, and for encapsulating the polymeric bumps, the conductive bumps and the pads, wherein the polymeric bumps are embedded in the adhesive film and a gap is defined between the polymeric bumps and the surface of the glass substrate.

2. The connection structure for a chip-on-glass driver IC according to claim 1, wherein the polymeric bumps are made of photosensitive polymer.

3. The connection structure for a chip-on-glass driver IC according to claim 2, wherein the photosensitive polymer is polyimide.

4. The connection structure for a chip-on-glass driver IC according to claim 1, wherein each of the conductive bumps is formed on a pad on the surface of the driver IC and at least one of the polymeric bumps surrounding the pad thereon; or each of the conductive bumps is directly formed on a pad on the surface of the driver IC.

5. The connection structure for a chip-on-glass driver IC according to claim 1, wherein the conductive bumps are arranged on a peripheral region of the surface of the driver IC, and the polymeric bumps are substantially arranged on a central region of the surface of the driver IC surrounded by the conductive bumps.

6. The connection structure for a chip-on-glass driver IC according to claim 1, wherein the coefficient of thermal expansion (CTE) of the polymeric bumps is greater than that of a substrate of the driver IC or that of the glass substrate.

7. The connection structure for a chip-on-glass driver IC according to claim 6, wherein the CTE difference between the polymeric bumps and the adhesive film is smaller than the CTE difference between the substrate of the driver IC and the adhesive film or the CTE difference between the glass substrate and the adhesive film.

8. The connection structure for a chip-on-glass driver IC according to claim 1, wherein the adhesive film is a non-conductive adhesive film (NCF).

9. The connection structure for a chip-on-glass driver IC according to claim 1, wherein the adhesive film is an anisotropic conductive film (ACF) having a plurality of conductive particles therein.

10. The connection structure for a chip-on-glass driver IC according to claim 9, wherein the height difference between the polymeric bumps and the conductive bumps is greater than the particle diameter of the conductive particles.

11. A connection method for a chip-on-glass driver IC, comprising:
providing a driver IC having a surface, a plurality of polymeric bumps and a plurality of conductive bumps, wherein the polymeric bumps and the conductive bumps are arranged on the surface and the height of the polymeric bumps relative to the surface is smaller than that of the conductive bumps relative to the surface; and
attaching the driver IC to a glass substrate via an adhesive film by thermal compression bonding, wherein the conductive bumps are electrically connected to a plurality of pads on the glass substrate, the polymeric bumps are embedded in the adhesive film, and a gap is defined between the polymeric bumps and a surface of the glass substrate.

12. The connection method for a chip-on-glass driver IC according to claim 11, wherein the step of providing the driver IC comprises:
providing a wafer having a surface formed with a plurality of pads;
forming a polymer layer on the surface of the wafer;
processing the polymer layer by processes of exposure and development to form a plurality of polymeric bumps;
forming a plurality of conductive bumps on the pads, wherein the height of the conductive bumps relative to the surface is greater than that of the polymeric bumps relative to the surface; and
cutting the wafer into a plurality of driver ICs.

13. The connection method for a chip-on-glass driver IC according to claim 12 wherein the polymer layer is made of photosensitive polymer.

14. The connection method for a chip-on-glass driver IC according to claim 13, wherein the photosensitive polymer is polyimide.

15. The connection method for a chip-on-glass driver IC according to claim 11, wherein each of the conductive bumps is formed on one of the pads on the surface of the driver IC and at least one of the polymeric bumps surrounding the pad thereon; or each of the conductive bumps is directly formed on one of the pads on the surface of the driver IC.

16. The connection method for a chip-on-glass driver IC according to claim 11, wherein the conductive bumps are arranged on a peripheral region of the surface of the driver IC, and the polymeric bumps are substantially arranged on a central region of the surface of the driver IC surrounded by the conductive bumps.

17. The connection method for a chip-on-glass driver IC according to claim 11, wherein the coefficient of thermal expansion (CTE) of the polymeric bumps is greater than that of a substrate of the driver IC and that of the glass substrate.

18. The connection method for a chip-on-glass driver IC according to claim 17, wherein the CTE difference between the polymeric bumps and the adhesive film is smaller than the CTE difference between the substrate of the driver IC and the adhesive film or the CTE difference between the glass substrate and the adhesive film.

19. The connection method for a chip-on-glass driver IC according to claim 11, wherein the adhesive film is a non-conductive adhesive film (NCF).

20. The connection method for a chip-on-glass driver IC according to claim 11, wherein the adhesive film is an anisotropic conductive film (ACF) having a plurality of conductive particles therein; and wherein the height difference between the polymeric bumps and the conductive bumps is greater than the particle diameter of the conductive particles.
